(19) United States
(12) Patent Application Publication
(10) Pub. No.: US 2024/0213327 A1
(43) Pub. Date: Jun. 27, 2024

(54) SUPERLATTICE BUFFER STRUCTURE AND SEMICONDUCTOR DEVICE HAVING THE SAME

(71) Applicant: Samsung Electronics Co., Ltd., Suwon-si (KR)

(72) Inventors: Boram KIM, Suwon-si (KR); Jaejoon OH, Suwon-si (KR); Jongseob KIM, Suwon-si (KR)

(73) Assignee: Samsung Electronics Co., Ltd., Suwon-si (KR)

(21) Appl. No.: 18/485,740

(22) Filed: Oct. 12, 2023

(30) Foreign Application Priority Data
Dec. 27, 2022 (KR) 10-2022-0186375

(51) Int. Cl. H01L 29/15; H01L 29/20; H01L 29/778

(52) U.S. Cl. CPC H01L 29/155; H01L 29/2003; H01L 29/7786

(57) ABSTRACT

Provided are a superlattice buffer structure and a semiconductor device having the superlattice buffer structure. The superlattice buffer structure includes a plurality of superlattice blocks, and each of the plurality of superlattice blocks has a structure in which a first layer including Al(1−x)GaxN (0≤x≤1) and a second layer including Al(1−y)GayN (0≤y≤1, x>y) are alternately stacked on each other.

### CROSS-REFERENCE TO RELATED APPLICATION

This application claims the benefit of Korean Patent Application No. 10-2022-0186375, filed on Dec. 27, 2022, in the Korean Intellectual Property Office, the disclosure of which is incorporated herein in its entirety by reference.

### BACKGROUND

Various example embodiments relate to a superlattice buffer structure for reducing bow in a nitride-based semiconductor thin film and/or a semiconductor device having the superlattice buffer.

Research to use a nitride semiconductor (e.g., a GaN-based material) for semiconductor devices, such as high-electric power devices, light-emitting elements, and/or the like, has been actively conducted. When a semiconductor device is implemented by stacking a nitride semiconductor layer on a substrate other than a nitride semiconductor substrate, a buffer structure is necessary or preferred between the substrate and the nitride semiconductor layer to reduce the likelihood of a defect caused by characteristic differences between a substrate material and a nitride semiconductor, for example, differences in one or more of the lattice constant, thermal expansion coefficient, and the like. When the buffer structure does not compensate for the defect caused by the characteristic differences between the substrate material and the nitride semiconductor, the vertical robustness of the semiconductor device may be weakened, and the characteristics of an active layer therein may deteriorate.

### SUMMARY

Provided is a superlattice buffer structure that may reduce an amount of and/or a propensity for bow.

Alternatively or additionally, provided is a semiconductor device including a superlattice buffer structure that may reduce an amount of and/or a propensity of a bow.

Additional aspects will be set forth in part in the description which follows and, in part, will be apparent from the description, or may be learned by practice of the various example embodiments.

According to some example embodiments, a superlattice buffer structure includes a plurality of superlattice blocks, wherein each of the plurality of superlattice blocks has a structure in which a first layer including Al(1−x)GaxN (0≤x≤1) and a second layer including Al(1−y)GayN (0≤y≤1, x>y) are alternately stacked on each other.

Alternatively or additionally according to various example embodiments, a semiconductor device includes a substrate, a superlattice buffer structure on the substrate, and an active layer on the superlattice buffer structure. The superlattice buffer structure includes a plurality of superlattice blocks, each of the plurality of superlattice blocks has a structure in which a first layer including Al(1−x)GaxN (0≤x≤1) and a second layer including Al(1−y)GayN (0≤y≤1, x>y) are alternately stacked on each other, and the plurality of superlattice blocks are have different average gallium compositions from one another.

### BRIEF DESCRIPTION OF THE DRAWINGS

These and/or other aspects will become apparent and more readily appreciated from the following description of various example embodiments, taken in conjunction with the accompanying drawings in which:

FIG. 1 is a schematic cross-sectional view of a semiconductor device according to some example embodiments;

FIG. 2 is a cross-sectional view of a superlattice buffer structure according to some example embodiments;

FIG. 3 is a graph showing a change in an average gallium composition according to a location of each superlattice block of a superlattice buffer structure according to some example embodiments;

FIGS. 4 and 5 are graphs showing a change in a doping concentration and a change in an average gallium composition according to a location of each superlattice block of a superlattice buffer structure according to some example embodiments;

FIG. 6 illustrates an example of a semiconductor device further including a first material layer and a second material layer in the semiconductor device of FIG. 1; and

FIG. 7 illustrates an example of applying a semiconductor device according to some example embodiments to a high electron mobility transistor.

### DETAILED DESCRIPTION

Reference will now be made in detail to some embodiments, examples of which are illustrated in the accompanying drawings, wherein like reference numerals refer to like elements throughout. In this regard, embodiments may have different forms and should not be construed as being limited to the descriptions set forth herein. Accordingly, example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a superlattice buffer structure according to various example embodiments and/or a semiconductor device having the same will be described in detail with reference to the accompanying drawings. Throughout the drawings, like reference numerals denote like elements, and sizes of components in the drawings may be exaggerated for convenience of explanation and clarity. Terms such as “first” and “second” are used herein merely to describe a variety of constituent elements, but the constituent elements are not limited by the terms. Such terms are used only for the purpose of distinguishing one constituent element from another constituent element.

As used herein, the singular forms “a,” “an,” and “the” are intended to include the plural forms as well, unless the context clearly indicates otherwise. Furthermore, when a part may “include” a certain constituent element, unless specified otherwise, it may not be construed to exclude another constituent element but may be construed to further include other constituent elements. Furthermore, the size or thickness of each constituent element illustrated in the drawings may be exaggerated for convenience of explanation and clarity. Furthermore, when a certain material layer is described as being present on a substrate or other layer, the material layer may be present in direct contact with the substrate or layer, or a third layer may be present therebetween. As a material forming each layer in the following embodiment is exemplary, other materials may be used therefor.

Furthermore, terms such as “. . . portion,” “. . . unit,” “. . . module,” and “. . . block” stated in the specification may signify a unit to process at least one function or operation and the unit may be embodied by hardware, software, or a combination of hardware and software.

The particular implementations shown and described herein are illustrative examples of the disclosure and are not intended to otherwise limit the scope of the disclosure in any way. For the sake of brevity, conventional electronics, control systems, software development and other functional aspects of the systems may not be described in detail. Furthermore, the connecting lines, or connectors shown in the various figures presented are intended to represent functional relationships and/or physical or logical couplings between the various elements. It should be noted that many alternative or additional functional relationships, physical connections or logical connections may be present in a practical device.

The use of the terms “a” and “an” and “the” and similar referents in the context of describing the disclosure are to be construed to cover both the singular and the plural.

The operations of all methods described herein can be performed in any suitable order unless otherwise indicated herein or otherwise clearly contradicted by context. Furthermore, the use of any and all examples, or language (e.g., “such as”) provided herein, is intended merely to better illuminate the disclosure and does not pose a limitation on the scope of the disclosure unless otherwise claimed.

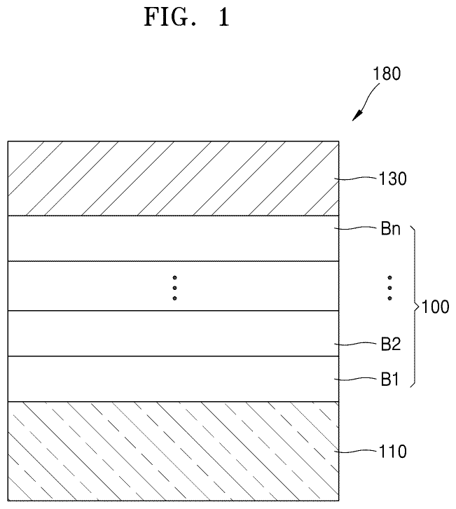

FIG. 1 is a schematic view of a semiconductor device 180 according to some example embodiments.

The semiconductor device 180 may include a substrate 110, a superlattice buffer structure 100 on the substrate 110, and an active layer 130 on the superlattice buffer structure 100.

The substrate 110 may include various materials. For example, the substrate 110 may include at least one of Si, SiC, sapphire, silicon on insulator (SOI), GaN, GaAs, InP, diamond, and Ge on insulator (GOI). However, example embodiments are not limited thereto.

The active layer 130 may include a III-V semiconductor layer such as a nitride semiconductor. For example, the active layer 130 may include a GaN-based material. In this case, the active layer 130 may include an undoped GaN-based material or a GaN-based material doped with certain impurities such as but not limited to boron, phosphorus, and/or arsenic. As a detailed example, the active layer 130 may include AlGaN/GaN.

The superlattice buffer structure 100 may be provided between the substrate 110 and the active layer 130. The superlattice buffer structure 100 may be provided to reduce the likelihood of and/or the impact from a defect caused by the characteristic differences (e.g., a lattice constant difference, a thermal expansion coefficient difference, and the like) between the material of the substrate 110 and the material of the active layer 130.

The superlattice buffer structure 100 may include a plurality of superlattice blocks B1, B2, . . . , Bn, where n is a natural number greater than one.

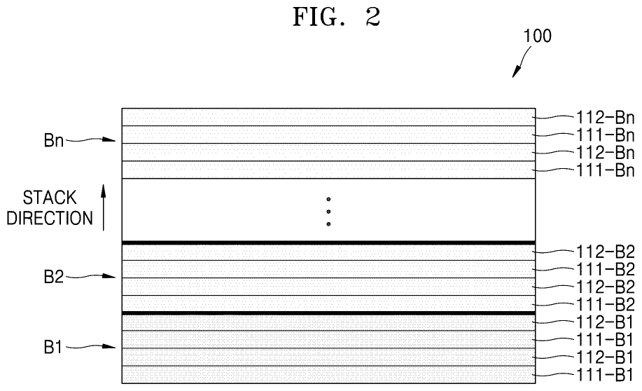

FIG. 2 a cross-sectional view of the superlattice buffer structure 100 according to some example embodiments.

In the superlattice buffer structure 100, each of the superlattice blocks B1, B2, . . . , Bn may have a structure in which a first layer including Al(1−x)GaxN (0≤x≤1) and a second layer including Al(1−y)GayN (0≤y≤1, x>y) are alternately stacked on each other. The superlattice blocks B1, B2, . . . , Bn may be configured to have different average gallium compositions from one another. The superlattice blocks B1, B2, . . . , Bn may be divided into groups having same x and y values.

The average gallium composition may be (x×Tx+y×Ty)/(Tx+Ty), wherein Tx denotes a total thickness sum of the first layer in a corresponding superlattice block, and Ty may denote a total thickness sum of the second layer in the corresponding superlattice block. The average gallium composition may be adjusted by adjusting one or more of four variables x, y, Tx, and Ty.

For example, a plurality of superlattice blocks may include a first superlattice block B1 and a second superlattice block B2. The first superlattice block B1 may have a structure in which a first layer 111-B1 and a second layer 112-B1 are alternately stacked on each other, and the second superlattice block B2 may have a structure in which a first layer 111-B2 and a second layer 112-B2 are alternately stacked on each other.

One of the first layer 111-B1 (111-B2) and the second layer 112-B1 (112-B2) may become or may correspond to a well layer, and the other may become or may correspond to a barrier layer. When the superlattice blocks B1 and B2 each include AlGaN, the superlattice blocks B1 and B2 may be classified into a well layer and a barrier layer according to a component ratio of Al. In detail, in the barrier layer, the component ratio of Al is higher than a component ratio of Ga, and in the well layer, the component ratio of Al may be lower than the component ratio of Ga.

In some example embodiments, a defect generated in the active layer 130 may be reduced in likelihood of occurrence and/or in impact from occurrence by adjusting the average gallium composition of each of the superlattice blocks B1, B2, . . . , Bn.

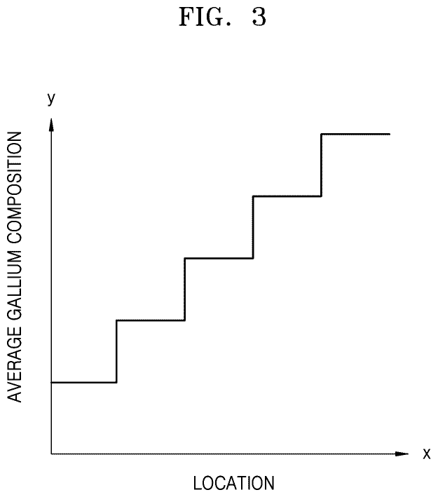

FIG. 3 schematically illustrates an average gallium composition according to the locations of the superlattice blocks B1, B2, . . . , Bn. The average gallium composition may be configured to increase, e.g., increase in a stepwise manner, e.g., by a constant amount, along a stack direction of the first layer and the second layer of a superlattice block. The average gallium composition may be adjusted such that an average gallium composition difference between neighboring superlattice blocks is constant. However, example embodiments are not limited thereto, and the average gallium composition difference may be changed as necessary. For example, the average gallium concentration may increase monotonically, e.g., monotonically concave-up or monotonically concave-down.

As described above, by adjusting the average gallium composition in a multi-step, a vertical leakage restriction effect and a bow reduction effect may be obtained. Alternatively or additionally, stress between the substrate 110 and the active layer 130 may be released step by step, and thus, strain due to the physical properties difference between the substrate 110 and the active layer 130 may be improved or effectively reduced. Alternatively or additionally, crystallinity of the superlattice blocks may be improved by multi-step growth, and generation of cracks in the superlattice blocks may be restricted.

The superlattice blocks B1, B2, . . . , Bn may each include a doped nitride semiconductor. The superlattice blocks B1, B2, . . . , Bn may each independently include any one or more than one dopant of one or more of carbon, iron, and magnesium. The dopant doping concentration may have a range of about 1E17 atoms/cm³ to about 1E21 atoms/cm³. The superlattice blocks B1, B2, . . . , Bn adjacent to each other may have different doping concentrations and/or different dopants. The superlattice blocks B1, B2, . . . , Bn may each have a thickness, for example, greater than about 0 and less than about 50000 nm.

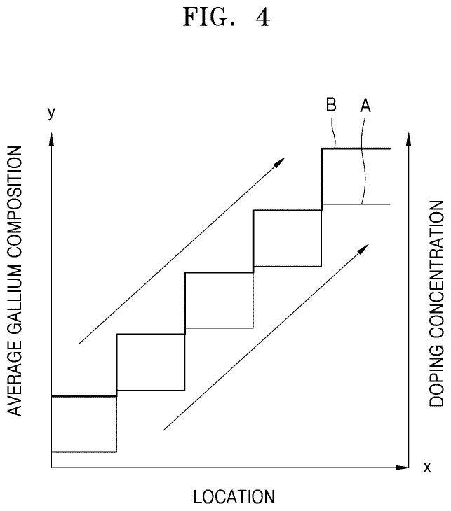

The defect generated in the active layer 130 may be reduced by adjusting the doping concentration of each of the superlattice blocks B1, B2, . . . , Bn. In some example embodiments, the defect generated in the active layer 130 may be further effectively reduced by adjusting the average gallium composition and the doping concentration together. FIG. 4 illustrates the average gallium composition and a change in the doping concentration according to the locations of the superlattice blocks. A denotes an average gallium composition, and B denotes a doping concentration. The average gallium composition and the doping concentration may be configured to increase together in the stack direction of the first layer and the second layer of the superlattice blocks B1, B2, . . . , Bn. Example embodiments are not necessarily limited thereto, and in some cases, the average gallium composition and the doping concentration may have a non-linear relationship with each other, depending on the superlattice block B1, B2, . . . , Bn.

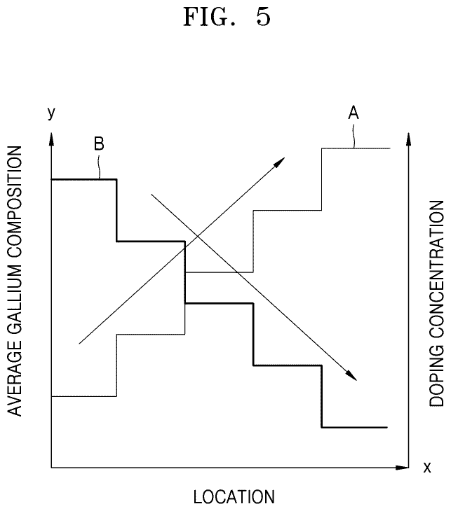

As illustrated in FIG. 5, it may be possible to increase the average gallium composition and decrease the doping concentration in the stack direction of the first layer and the second layer of the superlattice blocks B1, B2, . . . , Bn. By adjusting the average gallium composition and the doping concentration together, the vertical leakage restriction effect, the bow reduction effect, and a high temperature reverse bias (HTRB) characteristics improvement effect may be simultaneously obtained. Alternatively or additionally, the superlattice buffer structure 100 may reduce the likelihood of a dislocation due to the mismatch of a lattice constant between the substrate 110 and the active layer 130, and/or may restrict the generation of cracks due to the mismatch of a thermal expansion coefficient. As the thickness of the superlattice buffer structure 100 increases, compressive stress relaxation of the active layer 130 that grows on the superlattice buffer structure 100 may be reduced, and the defect may also be reduced. However, as the thickness of the superlattice buffer structure 100 increases, a process time increases, which is disadvantageous, so that there is a need to or desire to limit the thickness of the superlattice buffer structure 100 for appropriate defect reduction. For example, the thickness of the superlattice buffer structure 100 may be hundreds of nanometers to a few micrometers.

The superlattice blocks B1, B2, . . . , Bn may be formed through multi-step growth and/or deposition under a plurality of doping conditions, and not one doping condition. For example, in the first superlattice block B1, under a first doping condition, the first layer 111-B1 and the second layer 112-B1 may be grown and/or deposited to have a first doping concentration. In the second superlattice block B2, under a second doping condition different from the first doping condition, the first layer 111-B2 and the second layer 112-B2 may be grown and/or deposited to have a second doping concentration. Although in the above, a case in which each of the superlattice blocks B1, B2, . . . , Bn includes two layers is described, example embodiments are not limited thereto, and the superlattice blocks B1, B2, . . . , Bn may have a structure in which three or more layers are alternately stacked on each other. The superlattice blocks B1, B2, . . . , Bn may be formed, for example, by one or more of metal organic chemical vapor deposition (MOCVD), hydride vapor phase epitaxy (HVPE), molecular beam epitaxy (MBE), and the like. However, this is just an example.

The superlattice blocks B1, B2, . . . , Bn may be doped, for example, by one or more of an ion implantation process (e.g., at different doses and/or at different energies), an in-situ process, a plasma deposition process, a diffusion process, or the like. However, this is just an example. As described above, the superlattice blocks B1, B2, . . . , Bn may include a nitride semiconductor of a superlattice structure, and may be formed such that the doping concentration is changed step by step through a multi-step growth under a plurality of doping conditions. A doping profile suitable for the performance of the active layer 130 of the semiconductor device 180 may be implemented by adjusting the doping concentration of each superlattice block. In some example embodiments, by combining the average gallium composition and doping concentration of a superlattice block, vertical leakage characteristics may be improved, and simultaneously bow may be controlled.

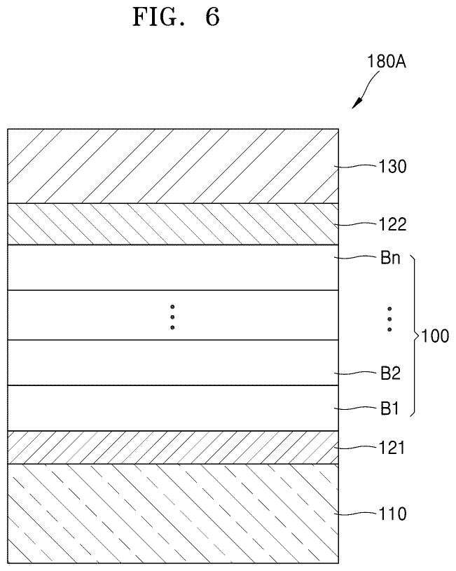

FIG. 6 illustrates an example of a semiconductor device 180A including a few more layers than the semiconductor device 180 of FIG. 1. In FIG. 6, the constituent elements having the same reference numerals as those of FIG. 1 substantially have the same function and configuration, and thus, detailed descriptions thereof are omitted. The semiconductor device 180A may further include a first material layer 121 between the substrate 110 and the superlattice buffer structure 100. The first material layer 121 may function, for example, as a nucleation layer. The first material layer 121 may include, for example, at least one of AlN, GaN, AlGaN, InGaN, AlInN, and AlGaInN. The first material layer 121 may prevent or reduce a melt-back phenomenon generated due to reaction between the substrate 110 and the active layer 130, and facilitate wetting of the superlattice buffer structure 100. In the growth process of the first material layer 121, an Al source may be first injected into deposition device before an N source. This may prevent or reduce a phenomena wherein, when ammonia that is the N source is first injected, the substrate 110 is exposed to ammonia to be nitrified.

Alternatively or additionally, the semiconductor device 180A may further include a second material layer 122 between the superlattice buffer structure 100 and the active layer 130. The second material layer 122 may be provided to effectively reduce a defect that may be generated between the superlattice buffer structure 100 and the active layer 130. The second material layer 122 may include a nitride semiconductor. The second material layer 122 may include at least one of AlN, GaN, AlGaN, InGaN, AlInN, and AlGaInN, but example embodiments are not limited thereto.

The semiconductor device 180A according to some example embodiments may be applicable to all devices needing GaN-based epitaxial growth, such as a power semiconductor device, an RF device, and the like. The semiconductor device 180A according to some example embodiments may be applicable to products in various fields, such as a fast charger, a power supply, an on-board charger, a LiDAR, robotics, and the like. When the superlattice buffer structure 100 according to some example embodiments is applied to a high electron mobility transistor (HEMT), a device capable of enduring a relatively high voltage, compared with a step-graded GaN buffer structure or a bulk GaN buffer structure, may be produced. Accordingly, the semiconductor device 180A according to various example embodiments may appropriately applied to a high voltage power device, such as a high efficiency switch device, an electric vehicle, and the like.

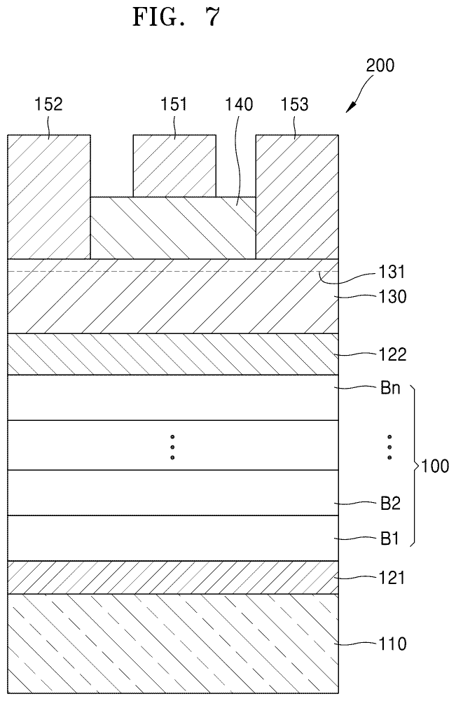

FIG. 7 illustrates an example of applying a semiconductor device according to some example embodiments to a high electron mobility transistor 200.

The high electron mobility transistor 200 may include the substrate 110, the superlattice buffer structure 100, the active layer 130, and a channel supply layer 140. The first material layer 121 may be provided between the substrate 110 and the superlattice buffer structure 100, and the second material layer 122 may be provided the superlattice buffer structure 100 and the active layer 130. In FIG. 7, constituent or correspond to elements using the same reference numerals as those of FIGS. 1 and 6 have substantially the same configuration, operation, and effect, detailed descriptions thereof are omitted.

The active layer 130 may operate as a channel layer. The active layer 130 may include a 2-dimensional electron gas (2DEG) layer 131. In the active layer 130, for example, the 2DEG layer 131 may be formed by spontaneous polarization (PSP) and piezo polarization (PPE), e.g., due to tensile strain.

As an example, the active layer 130 may be a GaN layer. In this case, the active layer 130 may be an undoped GaN layer, and in some cases, a GaN layer doped with certain impurities. A GaN-based semiconductor has good or excellent physical properties, such as one or more of a high energy bandgap, high thermal-chemical stability, a high electron saturation speed (up to 3×107 cm/sec), and the like so as to be applied not only as an optical device, but also as a high-frequency-high-output electronic device. An electronic device using a GaN-based semiconductor has various characteristics, such as a high breakdown electric field (up to 3×106 V/cm), a high maximum current density, a stable high-temperature operation characteristic, a high thermal conductivity, and the like. For the HEMT using a GaN-based heterogeneous junction structure, as band-discontinuity between the active layer (channel layer) 130 and the channel supply layer 140 is large, electrons may concentrate on a junction interface at a high concentration so that electron mobility may be increased.

The channel supply layer 140 may cause a 2DEG in the active layer 130. The 2DEG may be formed in the active layer 130 below the interface between the active layer 130 and the channel supply layer 140. The channel supply layer 140 may include a semiconductor material different from the semiconductor material forming the active layer 130. The semiconductor material of the channel supply layer 140 may be different from the semiconductor material of the active layer 130 in terms of at least one of polarization characteristics, energy bandgap, and lattice constant. For example, the semiconductor material of the channel supply layer 140 may have greater properties than the semiconductor material of the active layer 130 in terms of at least one of polarizability and energy bandgap.

The channel supply layer 140 may include, for example, a nitride including at least one of Al, Ga, and In, and have a single layer or multilayer structure. For example, the channel supply layer 140 may include any one of AlN, AlGaN, AlInN, AlGaInN, and a combination thereof. However, the disclosure is not limited thereto. The channel supply layer 140 may be either an undoped layer or a layer doped with certain impurities. The thickness of the channel supply layer 140 may be, for example, tens of nanometers (nm) or less. For example, the thickness of the channel supply layer 140 may be about 50 nm or less, but the disclosure is not limited thereto.

A source electrode 152 and a drain electrode 153 may be arranged on the active layer 130 to be apart from each other. A gate electrode 151 may be arranged on the channel supply layer 140. The source electrode 152 and the drain electrode 153 may be electrically connected to the 2DEG layer 131. In other words, the 2DEG layer 131 may be used as a current path (channel) between the source electrode 152 and the drain electrode 153.

By applying the superlattice buffer structure 100 according to some example embodiments to a high electron mobility transistor, the high electron mobility transistor may endure a high voltage and have improved device reliability.

The superlattice buffer structure according to some example embodiments may reduce the bow of an active layer by adjusting the average gallium composition of a plurality of superlattice blocks.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

It should be understood that various example embodiments described herein should be considered in a descriptive sense only and not for purposes of limitation. Descriptions of features or aspects within each embodiment should typically be considered as available for other similar features or aspects in other embodiments.

While one or more example embodiments have been described with reference to the figures, it will be understood by those of ordinary skill in the art that various changes in form and details may be made therein without departing from the spirit and scope as defined by the following claims.

What is claimed is:

1. A superlattice buffer structure comprising:
a plurality of superlattice blocks,
wherein each of the plurality of superlattice blocks has a structure in which a first layer including Al(1−x)GaxN (0≤x≤1) and a second layer including Al(1−y)GayN (0≤y≤1, x>y) are alternately stacked on each other, and the plurality of superlattice blocks are configured to have different average gallium compositions from one another.

2. The superlattice buffer structure of claim 1, wherein each of the plurality of superlattice blocks independently comprises a dopant of at least one of carbon, iron, and magnesium.

3. The superlattice buffer structure of claim 1, wherein the average gallium composition is (x×Tx+y×Ty)/(Tx+Ty), wherein Tx denotes a total thickness sum of a first layer in a corresponding superlattice block, and Ty denotes a total thickness sum of a second layer in the corresponding superlattice block.

4. The superlattice buffer structure of claim 1, wherein the average gallium composition of a superlattice block increases in a stack direction of the first layer and the second layer.

5. The superlattice buffer structure of claim 2, wherein a doping concentration of each of the plurality of superlattice blocks increases in a stack direction of the first layer and the second layer.

6. The superlattice buffer structure of claim 1, wherein a difference in the average gallium composition between neighboring superlattice blocks of the plurality of superlattice blocks is about 0.01 or more.

7. The superlattice buffer structure of claim 2, wherein a doping concentration of each of the plurality of superlattice blocks is in a range of about 1E17 atoms/cm³ to about 1E21 atoms/cm³.

8. The superlattice buffer structure of claim 1, wherein the average gallium composition is in a range of about 0.25 to about 0.95.

9. A semiconductor device comprising:
a substrate;
a superlattice buffer structure on the substrate; and
an active layer on the superlattice buffer structure,
wherein the superlattice buffer structure comprises a plurality of superlattice blocks,
each of the plurality of superlattice blocks has a structure in which a first layer including Al(1−x)GaxN (0≤x≤1) and a second layer including Al(1−y)GayN (0≤y≤1, x>y) are alternately stacked on each other, and
the plurality of superlattice blocks are configured to have different average gallium compositions from one another.

10. The semiconductor device of claim 9, wherein each of the plurality of superlattice blocks independently comprises a dopant of at least one of carbon, iron, and magnesium.

11. The semiconductor device of claim 9, wherein the average gallium composition is (x×Tx+y×Ty)/(Tx+Ty), wherein Tx denotes a total thickness sum of the first layer in a corresponding superlattice block, and Ty denotes a total thickness sum of the second layer in the corresponding superlattice block.

12. The semiconductor device of claim 9, wherein the average gallium composition of a superlattice block increases in a stack direction of the first layer and the second layer.

13. The semiconductor device of claim 10, wherein a doping concentration of each of the plurality of superlattice blocks increases in a stack direction of the first layer and the second layer.

14. The semiconductor device of claim 9, wherein a difference in the average gallium composition between neighboring superlattice blocks of the plurality of superlattice blocks is about 0.01 or more.

15. The semiconductor device of claim 10, wherein a doping concentration of each of the plurality of superlattice blocks is in a range of about 1E17 atoms/cm³ to about 1E21 atoms/cm³.

16. The semiconductor device of claim 9, wherein the average gallium composition is in a range of about 0.25 to about 0.95.

17. The semiconductor device of claim 9, further comprising:
a nucleation layer between the substrate and the superlattice buffer structure.

18. The semiconductor device of claim 9, further comprising:
a channel supply layer provided on the active layer and configured to generate a 2-dimensional electron gas in the active layer,
wherein a source electrode and a drain electrode are arranged on the active layer to be apart from each other, and a gate electrode is arranged on the channel supply layer.
